(19) United States
(12) Patent Application Publication
(10) Pub. No.: US 2025/0379047 A1
(43) Pub. Date: Dec. 11, 2025

(54) THIN AND HIGH-QUALITY OXIDE LAYERS

(71) Applicant: Applied Materials, Inc., Santa Clara, CA (US)

(72) Inventors: Jae Young PARK, Sunnyvale, CA (US); Young Jun CHOI, Gyeonggi-do (KR); Ho Chang LEE, Gyeonggi-do (KR); Jiseon PARK, Gyeonggi-do (KR); Hansel LO, San Jose, CA (US); Johanes F. SWENBERG, Los Gatos, CA (US); Paola DE CECCO, Prunedale, CA (US); Michael BOWES, Scotts Valley, CA (US); Andy LO, San Jose, CA (US); John Timothy BOLAND, Aptos, CA (US); Rene GEORGE, Redwood City, CA (US)

(21) Appl. No.: 18/735,032

(22) Filed: Jun. 5, 2024

(51) Int. Cl. H01L 21/02; H01L 21/324

(52) U.S. Cl. CPC H01L 21/02238; H01L 21/02164; H01L 21/02252; H01L 21/324

(57) ABSTRACT

The methods and devices described herein provide for thin and high-quality oxide layers with controlled interfacial roughness. In some embodiments, the aforementioned oxide layers are formed using radical oxidation processes with slow oxidation rates and relatively low-to-moderate temperatures, followed by nitrogen (N₂) annealing at relatively high temperatures to densify the oxide layer(s) while also relieving (e.g., relaxing) interfacial stresses by inducing the viscous flow of the oxide.

### BACKGROUND

### Field

Embodiments described herein generally relate to semiconductor device fabrication, and more particularly, to methods of forming thing and high-quality oxide layers for high aspect ratio semiconductor device structures.

### Description of the Related Art

The production of silicon integrated circuits has placed difficult demands on fabrication processes to increase the number of devices while decreasing the minimum feature sizes on a chip. These demands have extended to fabrication processes including depositing layers onto difficult topologies while maintaining device reliability. For example, a buried wordline (bWL) structure used in dynamic random-access memory (DRAM) devices may have an aspect ratio of 6:1, 10:1, or more, and require a gate oxide layer that is thin and reliable.

Conventional methods of forming an oxide layer in such structures, including gate oxides, suffer from one or more of a variety of issues. For example, current fabrication methods suffer from high silicon consumption for thermal oxidation growth, thereby resulting in oxide layers with increased thickness. Further, current deposition methods result in low quality oxide films with increased defects and traps within, leading to reduced overall device reliability.

There is thus a need for improved processes for forming thin and high-quality oxide layers for high aspect ratio semiconductor device structures.

### SUMMARY

Embodiments of the present disclosure provide a method for forming a semiconductor device, comprising: performing a radical oxidation process to oxidize a silicon-containing material of a substrate and at least partially convert the substrate to an interfacial layer, the radical oxidation process performed at a temperature between about 100° C. and about 600° C.; performing a temperature ramp-up, the substrate exposed to an oxidant-free ambient during the temperature ramp-up; performing an anneal process to densify the interfacial layer, the substrate exposed to the oxidant-free ambient during the anneal process, the anneal process performed at a temperature between about 800° C. and about 1200° C.; performing a temperature ramp-down, the substrate exposed to the oxidant-free ambient during the temperature ramp-down; and depositing an oxide layer over the annealed interfacial layer, the oxide layer deposited via atomic layer deposition (ALD).

Embodiments of the present disclosure provide method for forming a semiconductor device, comprising: performing a first radical oxidation process to oxidize a silicon-containing material of a substrate and at least partially convert the substrate to an interfacial layer, the first radical oxidation process performed at a temperature between about 100° C. and about 600° C.; performing a second radical oxidation process to further oxidize the silicon-containing material of the substrate and at least partially convert the substrate to a base oxide layer for a gate oxide structure, the second radical oxidation process performed at a temperature between about 700° C. and about 800° C.; performing a temperature ramp-up, the substrate exposed to an oxidant-free ambient during the temperature ramp-up; performing an anneal process to densify the interfacial layer and the base oxide layer, the substrate exposed to the oxidant-free ambient during the anneal process, the anneal process performed at a temperature between about 800° C. and about 1200° C.; and performing a temperature ramp-down, the substrate exposed to the oxidant-free ambient during the temperature ramp-down.

Embodiments of the present disclosure provide a method for forming a semiconductor device, comprising: performing a first radical oxidation process to oxidize a silicon-containing material of a substrate and at least partially convert the substrate to an interfacial layer, the first radical oxidation process performed at a temperature between about 100° C. and about 600° C.; performing a temperature ramp-up, the substrate exposed to an oxidant-free ambient during the temperature ramp-up; performing a second radical oxidation process to further oxidize the silicon-containing material of the substrate and at least partially convert the substrate to a base oxide layer for a gate oxide structure, the second radical oxidation process performed at a temperature between about 700° C. and about 1100° C.; and performing a temperature ramp-down, the substrate exposed to the oxidant-free ambient during the temperature ramp-down.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic view of a substrate processing system according to embodiments.

FIG. 2 is a schematic view of a substrate processing chamber according to embodiments.

FIG. 3 is a process flow diagram of a method of forming an oxide layer in a semiconductor structure, according to embodiments.

FIG. 4 is a graphical representation of the method of FIG. 3, according to embodiments.

FIG. 5 is an example device structure formed by the method of FIG. 3, according to embodiments.

FIG. 6 is a process flow diagram of a method of forming an oxide layer in a semiconductor structure, according to embodiments.

FIG. 7 is a graphical representation of the method of FIG. 6, according to embodiments.

FIG. 8 is an example device structure formed by the method of FIG. 6, according to embodiments of the present disclosure.

FIG. 9 is a process flow diagram of a method of forming an oxide layer in a semiconductor structure, according to embodiments.

FIG. 10 is a graphical representation of the method of FIG. 9, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein are directed to methods of forming high quality and thin oxide layers for semiconductor device structures, such as gate oxides for buried wordline (bWL) structures used in a dynamic random access memory (DRAM) devices, flash memory devices, programmable logic devices, CMOS devices, metal-oxide-semiconductor field-effect transistors (MOSFET), or the like.

Conventional methods of forming such oxide layers suffer from one or more of a variety of issues. For example, certain methods for fabricating gate oxides involve the deposition of a base oxide layer onto a silicon substrate via atomic layer deposition (ALD), followed by a post-deposition treatment to densify the ALD-deposited oxide layer. However, during the deposition process, a parasitic oxide layer may form between the ALD-deposited oxide layer and the substrate as a result of the oxidizing precursor utilized. This parasitic oxide layer is typically poor in quality and has a high trap density, leading to reduced overall device reliability.

Certain other methods for fabricating gate oxides involve direct oxidation on the silicon substrate via in-situ steam generation (ISSG), rapid thermal oxidation (RTO), or radical plasma oxidation (RPO). Of these, RPO is often performed utilizing a remote plasma source (RPS) in order to decouple, or separate, plasma generation parameters and in-situ process parameters, thereby enabling more flexible process temperatures. However, RPO can lead to unwanted surface etching of the silicon substrate due to volatile silicon oxide (SiO) formation during high-temperature and low-pressure operations. To prevent such silicon (Si) etching, an oxygen (O₂) ambient is often supplied to the processing volume. Yet, the application of an O₂ ambient can lead to unwanted and uneven oxide growth, leading to an increased thickness of any formed oxide layers, and/or an increase in roughness at silicon/oxide interfaces as a result of the non-uniform O₂ diffusion into silicon layers. The additional oxidation makes it difficult to implement thin interfacial layers, while the increase in roughness causes an increase in interfacial trap density (Dit), which reduces the overall reliability of the device.

Accordingly, conventional methods of forming oxide layers, such as gate oxides, suffer from increased trap density and unwanted increases in oxide thickness.

The methods and devices described herein address the issues above and provide for thin and high-quality oxide layers with controlled interfacial roughness. In some embodiments, the aforementioned oxide layers are formed using radical oxidation processes with slow oxidation rates and relatively low-to-moderate temperatures, followed by nitrogen (N₂) annealing at relatively high temperatures to densify the oxide layer(s) while also relieving (e.g., relaxing) interfacial stresses by inducing the viscous flow of the oxide.

In some embodiments, the methods described herein may be utilized to form thin and high-quality interfacial layers on silicon substrates (or other silicon layers), after which a gate oxide layer may be deposited thereon. In some embodiments, the methods described herein may be utilized to form the interfacial layer and the gate oxide layer.

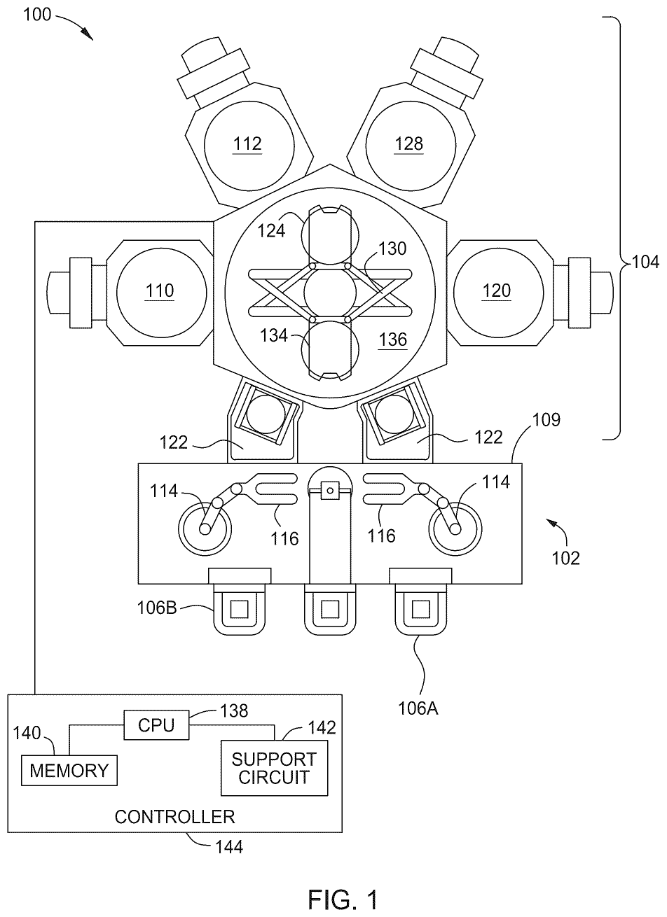

FIG. 1 shows a processing system 100 in accordance with one or more embodiments of the present disclosure. The embodiment shown in FIG. 1 is merely representative of one possible configuration and should not be taken as limiting the scope of the disclosure. For example, in some embodiments, the processing system 100 has a different number of processing chambers, load lock chambers, transfer chambers, and/or other components, and/or a configuration different from the illustrated embodiment.

The processing system 100 includes a processing platform 104 coupled with a factory interface 102 and a controller 144. In one or more embodiments, the processing system 100 may be adapted for use in a CENTURA® integrated processing system provided by Applied Materials, Inc., located in Santa Clara, California. It is contemplated that other processing systems (including those from other manufacturers) may be adapted to benefit from the present disclosure.

The processing platform 104 includes a plurality of processing chambers 110, 112, 120, 128, one or more load lock chambers 122, and a transfer chamber 136 that is coupled to the one or more load lock chambers 122.

The processing chambers 110, 112, 120, and 128 can be configured to perform any suitable process and provide any suitable process conditions. For example, one or more of the processing chambers 110, 112, 120, 128 may include an atomic layer deposition (ALD) chamber, a plasma enhanced chemical vapor deposition (PECVD) chamber, an epitaxy (EPI) chamber, a rapid thermal processing (RTP) chamber, a reactive ion etching (RIE) chamber, or other suitable chamber. In some embodiments, one or more of the processing chambers 110, 112, 120, 128 may be configured to function as an inductively coupled plasma (ICP) processing chamber, a capacitively coupled plasma (CCP) processing chamber, an etch soak chamber, a thermal processing chamber, a microwave plasma processing chamber, a UV exposure processing chamber, a laser processing chamber, a pumping chamber, an annealing chamber, and/or a metrology chamber or station. A processing chamber configured to operate as an ALD chamber may have a showerhead or vortex type gas injector. Whereas, a processing chamber configured to operate as a plasma chamber may have one or more electrodes and/or grounded plate configurations to generate a plasma while allowing a plasma gas to flow toward the wafer. In some embodiments, one or more of the processing chambers 110, 112, 120, 128 can be operably coupled to a remote plasma source (RPS) for remote plasma processing operations, e.g., remote plasma oxidation (RPO).

The transfer chamber 136 can be maintained under vacuum, or can be maintained at an ambient (e.g., atmospheric) pressure. Two load lock chambers 122 are shown in FIG. 1. Each of the load lock chambers 122 has a first port interfacing with the factory interface 102 and a second port interfacing with the transfer chamber 136. The transfer chamber 136 has a vacuum robot 130 disposed therein. The vacuum robot 130 has one or more blades 134 (two are shown in FIG. 1) capable of transferring the substrates 124 between the load lock chambers 122 and the processing chambers 110, 112, 120, and 128.

The factory interface 102 is coupled to the transfer chamber 136 through the load lock chambers 122. In one or more embodiments, the factory interface 102 includes at least one docking station 109 and at least one factory interface robot 114 to facilitate the transfer of substrates 124. The docking station 109 is configured to accept one or more front opening unified pods (FOUPs). Two FOUPS 106A, 106B are shown in the implementation of FIG. 1. The factory interface robot 114 having a blade 116 disposed on one end of the robot 114 is configured to transfer one or more substrates from the FOUPS 106A, 106B, through the load lock chambers 122, to the processing platform 104 for processing. Substrates being transferred can be stored at least temporarily in the load lock chambers 122.

The controller 144 is coupled to the processing system 100 and is used to control processes and methods, such as the operations of the methods described herein (for example the operations of the methods as described in other parts of the present disclosure). The controller 144 includes a central processing unit (CPU) 138, a memory 140 containing instructions, and support circuits 142 for the CPU. The controller 144 controls various items directly, or via other computers and/or controllers associated with particular process chamber and/or support system components.

The controller 144 can be a single controller that controls the entire processing system 100, or multiple controllers that control individual portions of the processing system 100. For example, the processing platform 100 may include separate controllers for each of the individual processing chambers 110, 112, 120, 128, the transfer chamber 136, the factory interface 102, the robots 114, etc.

The controller 144 may be one of any form of general-purpose computer processor that can be used in an industrial setting for controlling various chambers and sub-processors. The memory 140 or computer readable medium of the controller 144 may be one or more of readily available memory such as random access memory (RAM), read only memory (ROM), floppy disk, hard disk, optical storage media (e.g., compact disc or digital video disc), flash drive, or any other form of digital storage, local or remote. The memory 140 can retain an instruction set that is operable by the processor (CPU 138) to control parameters and components of the processing system 100.

The support circuits 142 are coupled to the CPU 138 for supporting the processor in a conventional manner. These circuits include cache, power supplies, clock circuits, input/output circuitry and subsystems, and the like. One or more processes may be stored in the memory 140 as software routine that, when executed or invoked by the processor, causes the processor to control the operation of the processing system 100 or individual processing chambers in the manner described herein. The software routine may also be stored and/or executed by a second CPU (not shown) that is remotely located from the hardware being controlled by the CPU 138.

Some or all of the processes and methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

In some embodiments, the controller 144 has one or more configurations to execute individual processes or sub-processes to perform the method. The controller 144 can be connected to and configured to operate intermediate components to perform the functions of the methods. For example, the controller 144 can be connected to and configured to control one or more of gas valves, actuators, motors, slit valves, vacuum control or other components.

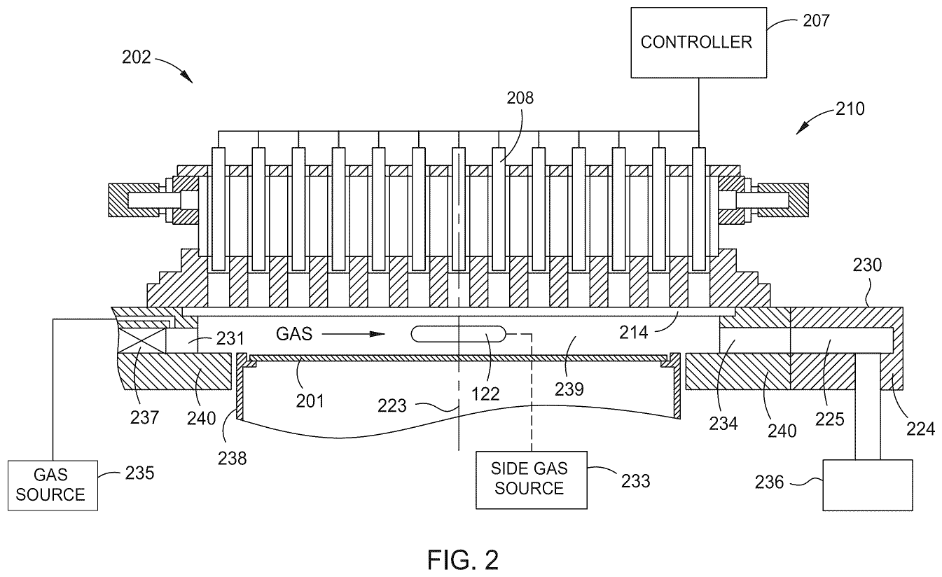

FIG. 2 is a schematic, cross-sectional representation of an example thermal processing chamber 202 that may be used to practice implementations of the present disclosure. The embodiment shown in FIG. 2 is merely representative of one possible configuration and should not be taken as limiting the scope of the disclosure. In some embodiments, the thermal processing chamber 202 is an example of a processing chamber in FIG. 1.

As shown, the thermal processing chamber 202 generally includes a lamp assembly 210, a chamber assembly 230 defining a processing volume 239, and a substrate support 238 disposed in the processing volume 239. The thermal processing chamber 202 is capable of providing a controlled thermal cycle that heats a substrate 201 for processes such as, for example, thermal annealing, thermal cleaning, chemical vapor deposition, atomic layer deposition, thermal oxidation, and thermal nitridation, etc.

The lamp assembly 210 may be positioned relatively above the substrate support 238 to supply heat to the processing volume 239 via a quartz window 214. The quartz window 214 is disposed between the substrate 201 and the lamp assembly 210. The lamp assembly 210 may additionally or alternatively be disposed relatively below the substrate support 238 in some implementations. It is noted that the term “above” or “below” as used in this disclosure are not referring to absolute directions. The lamp assembly 210 is configured to house a heating source 208, such as a plurality of tungsten-halogen lamps for providing a tailored infrared heating means to a substrate 201 disposed on the substrate support 238. The plurality of tungsten-halogen lamps may be disposed in a hexagonal arrangement. The heating source 208 may be connected to a controller 207 which may control the energy level of the heating source 208 to achieve a uniform or tailored heating profile to the substrate 201. In one example, the heating source 208 is capable of rapidly heating the substrate 201 at a rate of from about 50° C./s to about 280° C./s.

The substrate 201 may be heated to a temperature ranging from about 550 degrees Celsius to about less than 1200 degrees Celsius. The heating source 208 may provide zoned heating (temperature tuning) of the substrate 201. Temperature tuning may be performed to change the temperature of the substrate 201 at certain locations while not affecting the rest of the substrate temperature. In one implementation, the center of the substrate 201 is heated to a temperature that is 10 degrees Celsius to about 50 degrees Celsius higher than the temperature of the edge of the substrate 201.

A silt valve 237 may be disposed on the base ring 240 for a robot to transfer the substrate 201 into and out of the processing volume 239. The substrate 201 may be placed on the substrate support 238, which may be configured to move vertically and to rotate about a central axis 223. A gas inlet 231 may be disposed over the base ring 240 and connected to one or more gas sources 235 to provide one or more processing gases to the processing volume 239, such as hydrogen (H₂) or hydrogen containing gases, oxygen (O₂) or oxygen containing gases, nitrogen (N₂) or nitrogen containing gases (e.g., ammonia (NH₃)), and/or mixtures thereof. A gas outlet 234, formed on an opposite side of the base ring 240 from the gas inlet 231, is adapted to an exhaust assembly 224 which is in fluid communication with a pump system 236. The exhaust assembly 224 defines an exhaust volume 225, which is in fluid communication with the processing volume 239 via the gas outlet 234. The gas inlet 231 and gas outlet 234 are disposed on opposite sides of the processing volume 239, and under the vacuum force from the pump system 236, the main gas flow can be directed from the gas inlet 231 towards the gas outlet 234. Both of the gas inlet 231 and the gas outlet 234 may have a linear or azimuthal width which is approximately equal to a diameter of the substrate support 238.

In one implementation, one or more side ports 222 may be formed over the base ring 240 between the gas inlet 231 and the gas outlet 234. The side port 222, the gas inlet 231, and the gas outlet 234 may be disposed at substantially the same level or elevation. That is, the side port 222, the gas inlet 231, and the gas outlet 234 may be intersected by a common plane. The side ports 122 are connected to one or more side gas sources 233 configured to improve gas distribution uniformity near edge areas of the substrate 201. The one or more side gas sources 233 may provide gases such as hydrogen (H₂) or hydrogen containing gases, oxygen (O₂) or oxygen containing gases, nitrogen (N₂) or nitrogen containing gases (e.g., ammonia (NH₃)), and/or mixtures thereof. In some embodiments, the one or more side gas sources 233 include, or are coupled to, a remote radical source that generate radicals to the side port 222. In some embodiments, the one or more side gas sources 233 include, or are coupled to, a remote plasma source (RPS) that produces radicals (e.g., hydrogen radicals) to the side port 222.

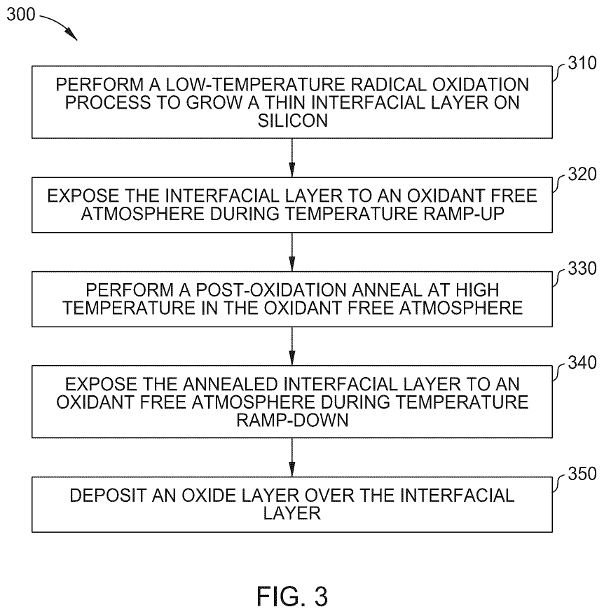

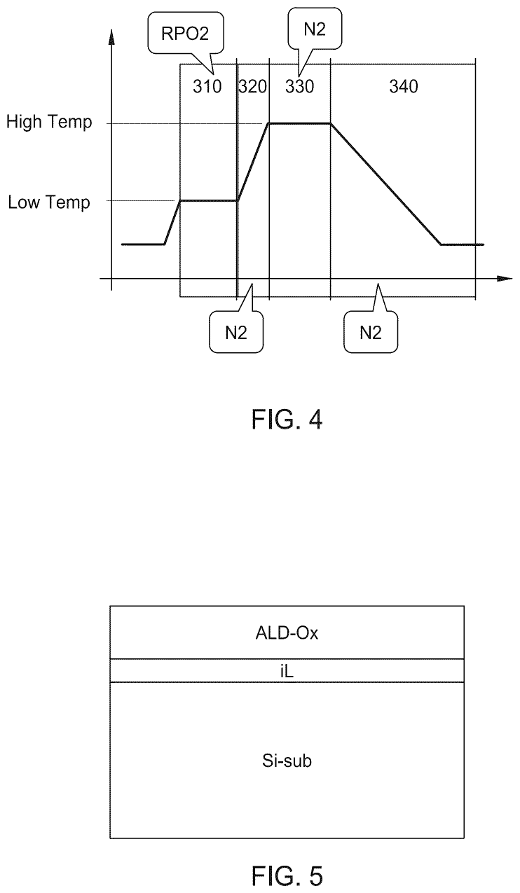

FIG. 3 depicts a process flow diagram of a method 300 for forming an oxide layer of a semiconductor structure, according to embodiments of the present disclosure. FIG. 4 depicts a graphical representation of the method 300, according to embodiments of the present disclosure. FIG. 5 depicts an example device structure 500 formed by the method 300, according to embodiments of the present disclosure. For clarity, FIGS. 3-5 are herein described together for clarity. It should be understood that the operations depicted in FIGS. 3 and 4 may be performed simultaneously and/or in a different order than the order depicted in FIGS. 3 and 4.

The method 300 begins at block 310, in which a silicon-containing substrate 510 is exposed to a low-temperature radical oxidation process to grow, or form, a thin and high-quality interfacial layer 520 on the substrate 510. Generally, radical oxidation at low temperatures not only reduces interfacial roughness, but also facilitates the formation of thin interfacial layers (e.g., less than or about 10 Å) due to the slow oxidation rate.

During the radical oxidation process, at least a portion of the substrate 510 is oxidized to at least partially convert the silicon-containing material of the substrate to silicon oxide by a plasma radical oxidation process, such as remote plasma oxidation (RPO). The radical oxidation process may be performed in a processing chamber, such as one of the processing chambers 110, 112, 120, and 128 shown in FIG. 1, and/or the processing chamber 202 shown in FIG. 2. The converted silicon oxide may form the interfacial layer 520 as shown in FIG. 5.

In a plasma radical oxidation process, oxygen radicals (O*) are directed to the silicon-containing substrate 510, and thus the oxidation of the silicon-containing material occurs. In some embodiments, the plasma radical oxidation process may use an oxidizing agent including oxygen (O₂), nitric oxide (NO), nitrous oxide (N₂O), or the like, to provide oxygen radicals (O*). These may be used alone or in a combination thereof. Further, the plasma radical oxidation process may use a source gas for generating plasma including any combination of hydrogen (H₂) (of content ratio of 0% and about 80%), argon (Ar), helium (He), and xenon (Xe), among others. These may be used alone or in a combination thereof. For example, the source gas may include a combination of O₂ and Ar, O₂ and H₂, or O₂ and H₂ and Ar, among others.

In some embodiments, the radical oxidation process may allow an oxidation reaction at a temperature of between about 100° C. and 600° C. for a soak time of between about 3 seconds and about 3 minutes, to ensure high quality of the oxidized silicon. In some embodiments, the radical oxidation process is performed at a temperature of between about 100° C. and 500° C., or between about 100° C. and 400° C., or between about 100° C. and 300° C., or between about 100° C. and 200° C., or between about 200° C. and 500° C., or between about 200°° C. and 400° C., or between about 200° C. and 300° C., or between about 300° C. and 600° C., or between about 300° C. and 500° C., or between about 300° C. and 400° C., or between about 400° C. and 600° C., or between about 400° C. and 500° C., or between about 500° C. and 600° C., or a similar range.

In some embodiments, the radical oxidation process may be performed under a pressure of between about 500 mTorr and about 10 Torr. In some embodiments, the radical oxidation process may be performed under a pressure of between about 1 Torr and about 10 Torr, or a pressure of between about 1 Torr and about 8 Torr, or a pressure of between about 1 Torr and about 6 Torr, or a pressure of between about 1 Torr and about 4 Torr, or a pressure of between about 1 Torr and about 2 Torr, or a pressure of between about 2 Torr and about 10 Torr, or a pressure of between about 2 Torr and about 8 Torr, or a pressure of between about 2 Torr and about 6 Torr, or a pressure of between about 2 Torr and about 4 Torr, or a pressure of between about 4 Torr and about 10 Torr, or a pressure of between about 4 Torr and about 8 Torr or a pressure of between about 4 Torr and about 6 Torr, or a pressure of between about 6 Torr and about 10 Torr or a pressure of between about 6 Torr and about 8 Torr, or a pressure of between about 8 Torr and about 10 Torr, or similar range.

The pressure may control an influx of the oxidizing agent against the substrate 510. The influx of the oxidizing agent may be controlled also by applying a bias during the radical oxidation process. Thus, a thickness and content of the interfacial layer 520 may be controlled and adjusted as desired, by adjusting oxidation temperature and oxidation time of the radical oxidation process. For example, a radical oxidation process at a higher oxidation temperature and a longer oxidation time duration may lead to a thicker silicon interfacial layer 520.

In some embodiments, the thickness of the interfacial layer 520 formed by the radical oxidation process at block 310 can be between about 1 Å and about 20 Å, or between about 1 Å and about 15 Å, or between about 1 Å and about 10 Å, or between about 1 Å and about 5 Å, or between about 1 Å and about 20 Å, or between about 5 Å and about 20 Å, or between about 5 Å and about 15 Å, or between about 5 Å and about 10 Å, or between about 10 Å and about 20 Å, or between about 10 Å and about 15 Å, or between about 15 Å and about 20 Å, or similar range.

At block 320, a temperature ramp-up is performed. During the temperature ramp-up, the temperature within the processing chamber is increased at a ramp rate of between about 10° C./s and about 300° C./s, or more, until a desired temperature for post-oxidation annealing is reached. In some embodiments, the ramp-up rate is between about 10° C./s and about 200° C./s, or between 10° C./s and about 100° C./s, or between 100° C./s and about 300° C./s, or between 100° C./s and about 200° C./s, or between 200° C./s and about 300° C./s, or similar range. In some embodiments, the temperature ramp-up is performed for between about 3 seconds and about 20 seconds, such as between about 5 seconds and about 15 seconds, such as about 10 seconds, or similar duration.

In some embodiments, the temperature ramp-up at block 320 is performed in an oxidant-free atmosphere to inhibit further oxidation of the substrate 510 and maintain the low interfacial roughness of the interfacial layer 520 formed by the slow radical oxidation process at block 310. Accordingly, in some embodiments where blocks 310-340 are performed in the same processing chamber, the oxygen radicals in the chamber may be purged at block 320, and N₂ gas or another inert gas may be flowed into the processing chamber. In some embodiments, however, the substrate 510 (now having the interfacial layer 520 formed thereon) may be transferred to another processing chamber for temperature ramp-up and/or annealing, wherein the substrate 510 may be exposed to N₂ gas or another inert gas.

In some embodiments, the temperature ramp-up at block 320 may be performed under a pressure of between about 500 m Torr and about 10 Torr. In some embodiments, the temperature ramp-up may be performed under a pressure of between about 1 Torr and about 10 Torr, or a pressure of between about 1 Torr and about 8 Torr, or a pressure of between about 1 Torr and about 6 Torr, or a pressure of between about 1 Torr and about 4 Torr, or a pressure of between about 1 Torr and about 2 Torr, or a pressure of between about 2 Torr and about 10 Torr, or a pressure of between about 2 Torr and about 8 Torr, or a pressure of between about 2 Torr and about 6 Torr, or a pressure of between about 2 Torr and about 4 Torr, or a pressure of between about 4 Torr and about 10 Torr, or a pressure of between about 4 Torr and about 8 Torr or a pressure of between about 4 Torr and about 6 Torr, or a pressure of between about 6 Torr and about 10 Torr or a pressure of between about 6 Torr and about 8 Torr, or a pressure of between about 8 Torr and about 10 Torr, or similar range.

At block 330, a high-temperature post-oxidation anneal (POA) process is performed. During the anneal process, at least a portion of the interfacial layer 520 is annealed to densify the formed oxide film. The radical oxidation process may be performed in a processing chamber, such as the same processing chambers as block 310 and/or block 320, or a different processing chamber.

In some embodiments, the anneal process at block 330 is performed in an oxidant-free atmosphere. For example, in some embodiments, the anneal process is performed in a N₂ gas ambient, or another inert gas ambient.

In some embodiments, the anneal process at block 330 is performed at a high temperature of between about 100° C. and 500° C., or between about 800° C. and 1200° C., or between about 800° C. and 1100° C., or between about 800° C. and 1000° C., or between about 800° C. and 900° C., or between about 900° C. and 1200° C., or between about 900° C. and 1100° C., or between about 900° C. and 1000° C., or between about 1000° C. and 1200° C., or between about 1000° C. and 1100° C., or between about 1100° C. and 1200° C., or a similar range. The high temperature of the anneal process, in addition to the inert ambient, facilitates improved quality of the oxide/dielectric film formed at block 310 by: (a) inducing the viscous flow of oxide, which relieves interfacial stress between the interfacial layer 520 and the substrate 510; (b) outgassing impurities from the oxide film to density the film; and (3) passivating oxygen vacancies and interfacial traps formed during block 310 with remaining trace amounts of oxidants.

In some embodiments the anneal process is performed for a period of between about 3 seconds and about 5 minutes, or more. For example, in some embodiments, the anneal process is performed for a period of between about 3 seconds and about 4 minutes, or for a period of between about 3 seconds and about 3 minutes, or for a period of between about 3 seconds and about 2 minutes, or for a period of between about 3 seconds and about 1 minute, or for a period of between about 1 minute and about 5 minutes, or for a period of between about 1 minute and about 4 minutes, or for a period of between about 1 minute and about 3 minutes, or for a period of between about 1 minute and about 2 minutes, or for a period of between about 2 minutes and about 5 minutes, or for a period of between about 2 minutes and about 4 minutes, or for a period of between about 2 minutes and about 3 minutes, or for a period of between about 3 minutes and about 5 minutes, or for a period of between about 3 minutes and about 4 minutes or for a period of between about 4 minutes and about 5 minutes, or similar duration.

In some embodiments, the anneal process at block 330 may be performed under a pressure of between about 500 m Torr and about 10 Torr. In some embodiments, the anneal process may be performed under a pressure of between about 1 Torr and about 10 Torr, or a pressure of between about 1 Torr and about 8 Torr, or a pressure of between about 1 Torr and about 6 Torr, or a pressure of between about 1 Torr and about 4 Torr, or a pressure of between about 1 Torr and about 2 Torr, or a pressure of between about 2 Torr and about 10 Torr, or a pressure of between about 2 Torr and about 8 Torr, or a pressure of between about 2 Torr and about 6 Torr, or a pressure of between about 2 Torr and about 4 Torr, or a pressure of between about 4 Torr and about 10 Torr, or a pressure of between about 4 Torr and about 8 Torr or a pressure of between about 4 Torr and about 6 Torr, or a pressure of between about 6 Torr and about 10 Torr or a pressure of between about 6 Torr and about 8 Torr, or a pressure of between about 8 Torr and about 10 Torr, or similar range.

At block 340, a temperature ramp-down is performed. During the temperature ramp-down, the temperature within the processing chamber is decreased at a ramp rate of about 10° C./s, or more, until a desired temperature for deposition is reached. In some embodiments, the ramp-down rate is between about 10° C./s and 300° C./s. In some embodiments, the ramp-down rate is between about 10° C./s and about 200° C./s, or between 10° C./s and about 100° C./s, or between 100° C./s and about 300° C./s, or between 100° C./s and about 200° C./s, or between 200° C./s and about 300° C./s, or similar range. In some embodiments, the temperature ramp-down is performed for between about 3 seconds and about 20 seconds, such as between about 5 seconds and about 15 seconds, such as about 10 seconds, or similar duration.

In some embodiments, the temperature ramp-down at block 340 is performed in an oxidant-free atmosphere to inhibit further oxidation and maintain the low interfacial roughness of the interfacial layer 520 formed at block 310. For example, in some embodiments, the temperature ramp-down is performed in a N₂ gas ambient, or another inert gas ambient.

Finally, at block 350, an oxide layer 530 may be deposited over the interfacial layer 520. The deposition process at block 350 may be any appropriate deposition process, such as atomic layer deposition (ALD), epitaxial deposition, chemical vapor deposition (CVD), physical vapor deposition (PVD), or the like performed in a processing chamber, such as the processing chambers 110, 112, 120, and 128 shown in FIG. 1.

The deposited oxide layer 530 may generally be utilized as a gate oxide for a buried wordline (bWL) structure or a metal-oxide-semiconductor field-effect transistor (MOSFET), or for other types of semiconductor devices, such as nanowires, that require a thin and high-quality oxide layer. In specific examples, the structure described above may be utilized in a dynamic random-access memory (DRAM) device, a flash memory device, a programmable logic device, a CMOS device, or the like.

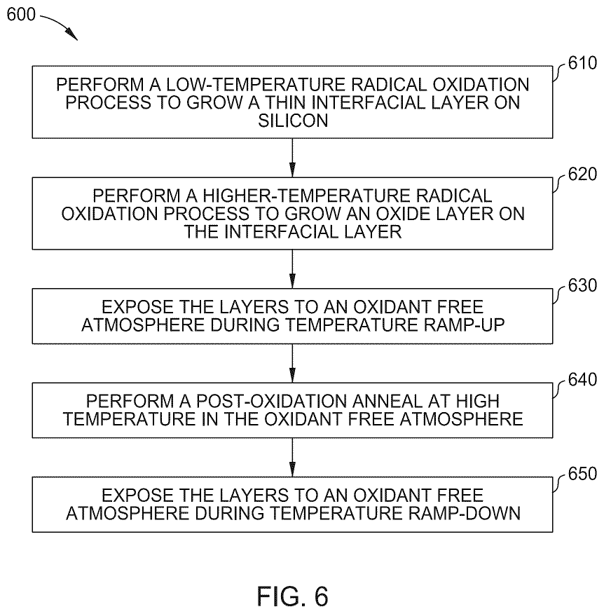

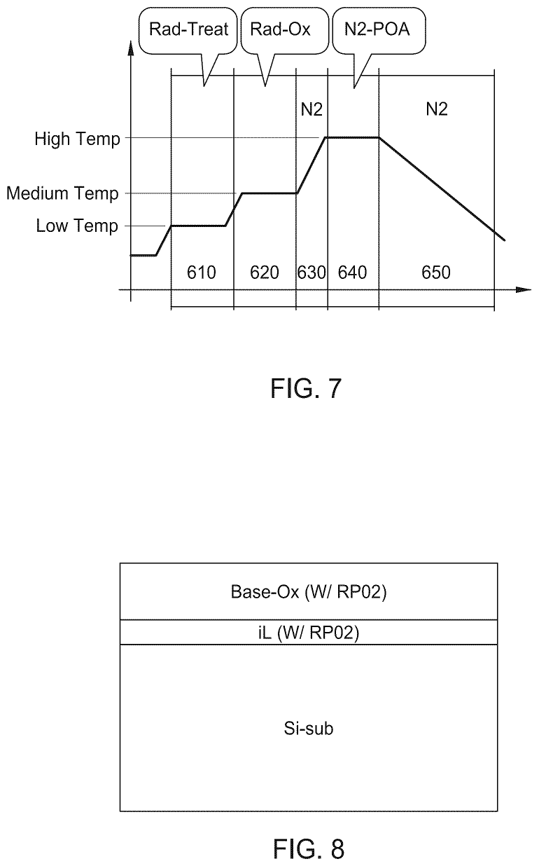

FIG. 6 depicts a process flow diagram of a method 600 for forming an oxide layer of a semiconductor structure, according to embodiments of the present disclosure. FIG. 7 depicts a graphical representation of the method 600, according to embodiments of the present disclosure. FIG. 8 depicts an example device structure 800 formed by the method 600, according to embodiments of the present disclosure. For clarity, FIGS. 6-8 are herein described together for clarity. It should be understood that the operations depicted in FIGS. 6 and 7 may be performed simultaneously and/or in a different order than the order depicted in FIGS. 6 and 7.

The method 600 begins at block 610, in which a silicon-containing substrate 810 is exposed to a low-temperature radical oxidation process to grow, or form, a thin and high-quality interfacial layer 820 on the substrate 810. Generally, radical oxidation at low temperatures not only reduces interfacial roughness, but also facilitates the formation of thin interfacial layers (e.g., less than or about 10 Å) due to the slow oxidation rate.

During the radical oxidation process, at least a portion of the substrate 810 is oxidized to at least partially convert the silicon-containing material of the substrate to silicon oxide by, e.g., a plasma radical oxidation process, such as remote plasma oxidation (RPO). The radical oxidation process may be performed in a processing chamber, such as one of the processing chambers 110, 112, 120, and 128 shown in FIG. 1, and/or the processing chamber 202 shown in FIG. 2. The converted silicon oxide may form the interfacial layer 820 as shown in FIG. 8.

In a plasma radical oxidation process, oxygen radicals (O*) are directed to the silicon-containing substrate 810, and thus the oxidation of the silicon-containing material occurs. In some embodiments, the plasma radical oxidation process may use an oxidizing agent including oxygen (O₂), nitric oxide (NO), nitrous oxide (N₂O), or the like, to provide oxygen radicals (O*). These may be used alone or in a combination thereof. Further, the plasma radical oxidation process may use a source gas for generating plasma including any combination of hydrogen (H₂) (of content ratio of 0% and about 80%), argon (Ar), helium (He), and xenon (Xe), among others. These may be used alone or in a combination thereof. For example, the source gas may include a combination of O₂ and Ar, O₂ and H₂, or O₂ and H₂ and Ar, among others.

In some embodiments, the radical oxidation process may allow an oxidation reaction at a temperature of between about 100° C. and 600° C. for a soak time of between about 3 seconds and about 3 minutes, to ensure high quality of the oxidized silicon. In some embodiments, the radical oxidation process is performed at a temperature of between about 100° C. and 500° C., or between about 100° C. and 400° C., or between about 100° C. and 300° C., or between about 100° C. and 200° C., or between about 200° C. and 500° C., or between about 200° C. and 400° C., or between about 200° C. and 300° C., or between about 300° C. and 600° C., or between about 300° C. and 500° C., or between about 300° C. and 400° C., or between about 400° C. and 600° C., or between about 400° C. and 500° C., or between about 500° C. and 600° C., or a similar range.

In some embodiments, the radical oxidation process is performed for a period of between about 3 seconds and about 2 minutes, or for a period of between about 3 seconds and about 1 minute, or for a period of between about 30 seconds and about 3 minutes, or for a period of between about 30 seconds and about 2 minutes, or for a period of between about 30 seconds and about 1 minute, or for a period of between about 1 minute and about 3 minutes, or for a period of between about 1 minute and about 2 minutes, or for a period of between about 2 minutes and about 3 minutes, or similar duration.

In some embodiments, the radical oxidation process may be performed under a pressure of between about 500 mTorr and about 10 Torr. In some embodiments, the radical oxidation process may be performed under a pressure of between about 1 Torr and about 10 Torr, or a pressure of between about 1 Torr and about 8 Torr, or a pressure of between about 1 Torr and about 6 Torr, or a pressure of between about 1 Torr and about 4 Torr, or a pressure of between about 1 Torr and about 2 Torr, or a pressure of between about 2 Torr and about 10 Torr, or a pressure of between about 2 Torr and about 8 Torr, or a pressure of between about 2 Torr and about 6 Torr, or a pressure of between about 2 Torr and about 4 Torr, or a pressure of between about 4 Torr and about 10 Torr, or a pressure of between about 4 Torr and about 8 Torr or a pressure of between about 4 Torr and about 6 Torr, or a pressure of between about 6 Torr and about 10 Torr or a pressure of between about 6 Torr and about 8 Torr, or a pressure of between about 8 Torr and about 10 Torr, or similar range.

The pressure may control an influx of the oxidizing agent against the substrate 810. The influx of the oxidizing agent may be controlled also by applying a bias during the radical oxidation process. Thus, a thickness and content of the interfacial layer 820 may be controlled and adjusted as desired, by adjusting oxidation temperature and oxidation time of the radical oxidation process. For example, a radical oxidation process at a higher oxidation temperature and a longer oxidation time duration may lead to a thicker silicon interfacial layer 820.

In some embodiments, the thickness of the interfacial layer 820 formed by the radical oxidation process at block 310 can be between about 1 Å and about 20 Å, or between about 1 Å and about 15 Å, or between about 1 Å and about 10 Å, or between about 1 Å and about 5 Å, or between about 1 Å and about 20 Å, or between about 5 Å and about 20 Å, or between about 5 Å and about 15 Å, or between about 5 Å and about 10 Å, or between about 10 Å and about 20 Å, or between about 10 Å and about 15 Å, or between about 15 Å and about 20 Å, or similar range.

At block 620, a second radical oxidation process is performed to grow, or form, an oxide layer 830 over the substrate interfacial layer 820. The radical oxidation process may be performed in a processing chamber, such as one of the processing chambers 110, 112, 120, and 128 shown in FIG. 1, and/or the processing chamber 202 shown in FIG. 2.

In some embodiments, the second radical oxidation process at block 620 is a plasma radical oxidation process, such as remote plasma oxidation (RPO). In some embodiments, the plasma radical oxidation process may use an oxidizing agent including oxygen (O₂), nitric oxide (NO), nitrous oxide (N₂O), or the like, to provide oxygen radicals (O*). These may be used alone or in a combination thereof. Further, the plasma radical oxidation process may use a source gas for generating plasma including any combination of hydrogen (H₂) (of content ratio of 0% and about 80%), argon (Ar), helium (He), and xenon (Xe), among others. These may be used alone or in a combination thereof. For example, the source gas may include a combination of O₂ and Ar, O₂ and H₂, or O₂ and H₂ and Ar, among others.

In some embodiments, the second radical oxidation process may be performed at a higher temperature as compared to the first radical oxidation process at block 610. For example, the second radical oxidation process may be performed at a temperature of between about 700° C. and 800° C. for a soak time of between about 3 seconds and about 3 minutes. In some embodiments, the second radical oxidation process is performed for a period of between about 3 seconds and about 2 minutes, or for a period of between about 3 seconds and about 1 minute, or for a period of between about 30 seconds and about 3 minutes, or for a period of between about 30 seconds and about 2 minutes, or for a period of between about 30 seconds and about 1 minute, or for a period of between about 1 minute and about 3 minutes, or for a period of between about 1 minute and about 2 minutes, or for a period of between about 2 minutes and about 3 minutes, or similar duration.

In some embodiments, the second radical oxidation process may be performed under a pressure of between about 500 m Torr and about 10 Torr. In some embodiments, the radical oxidation process may be performed under a pressure of between about 500 mTorr and about 10 Torr. In some embodiments, the radical oxidation process may be performed under a pressure of between about 1 Torr and about 10 Torr, or a pressure of between about 1 Torr and about 8 Torr, or a pressure of between about 1 Torr and about 6 Torr, or a pressure of between about 1 Torr and about 4 Torr, or a pressure of between about 1 Torr and about 2 Torr, or a pressure of between about 2 Torr and about 10 Torr, or a pressure of between about 2 Torr and about 8 Torr, or a pressure of between about 2 Torr and about 6 Torr, or a pressure of between about 2 Torr and about 4 Torr, or a pressure of between about 4 Torr and about 10 Torr, or a pressure of between about 4 Torr and about 8 Torr or a pressure of between about 4 Torr and about 6 Torr, or a pressure of between about 6 Torr and about 10 Torr or a pressure of between about 6 Torr and about 8 Torr, or a pressure of between about 8 Torr and about 10 Torr, or similar range.

The pressure may control an influx of the oxidizing agent. The influx of the oxidizing agent may be controlled also by applying a bias during the radical oxidation process. Thus, a thickness and content of the oxide layer 830 may be controlled and adjusted as desired, by adjusting oxidation temperature and oxidation time of the radical oxidation process. For example, a radical oxidation process at a higher oxidation temperature and a longer oxidation time duration may lead to a thicker oxide layer 830.

During the second radical oxidation process at block 620, the pre-grown interfacial layer 820 plays a role as a buffer layer to retard/slow the oxidation rate of the oxide layer 830. This, in turn, facilitates a reduction in bulk traps by allowing the formation of a more stoichiometric oxide, as well as a reduction in interfacial trap density by efficiently passivating the interfacial traps.

Generally, the oxide layer 830 may be utilized as a base oxide for the formation of a gate oxide for a metal-oxide-semiconductor field-effect transistor (MOSFET), a dynamic random access memory (DRAM) device, a flash memory device, a programmable logic device, a CMOS device, or for other types of semiconductor devices, such as nanowires, that require a thin and high-quality oxide layer.

At block 630, a temperature ramp-up is performed. During the temperature ramp-up, the temperature within the processing chamber is increased at a ramp rate of about 10° C./s, or more, until a desired temperature for post-oxidation annealing is reached. In some embodiments, the ramp-up rate is between about 10° C./s and about 300° C./s. For example, in some embodiments, the ramp-up rate is between about 10° C./s and about 200° C./s, or between 10° C./s and about 100° C./s, or between 100° C./s and about 300° C./s, or between 100° C./s and about 200° C./s, or between 200° C./s and about 300° C./s, or similar range. In some embodiments, the temperature ramp-up is performed for between about 3 seconds and about 20 seconds, such as between about 5 seconds and about 15 seconds, such as about 10 seconds, or similar duration.

In some embodiments, the temperature ramp-up at block 630 is performed in an oxidant-free atmosphere to inhibit further oxidation of the substrate 810 and maintain low interfacial roughness of the interfacial layer 820 and the oxide layer 830. Accordingly, in some embodiments where blocks 610-650 are performed in the same processing chamber, the oxygen radicals in the chamber may be purged at block 630, and N₂ gas or another inert gas may be flowed into the processing chamber. In some embodiments, however, the substrate 810 (now having the interfacial layer 820 and oxide layer 830 formed thereon) may be transferred to another processing chamber for temperature ramp-up and/or annealing, wherein the substrate 810 may be exposed to N₂ gas or another inert gas.

During the temperature ramp-up at block 630, the pre-grown interfacial layer 820 prevents silicon sublimation at the higher temperatures, which often occurs in more conventional processes and can lead to further undesired oxidation and increased interfacial roughness between layers.

In some embodiments, the temperature ramp-up at block 630 may be performed under a pressure of between about 500 m Torr and about 10 Torr. In some embodiments, the temperature ramp-up may be performed under a pressure of between about 500 mTorr and about 10 Torr. In some embodiments, the radical oxidation process may be performed under a pressure of between about 1 Torr and about 10 Torr, or a pressure of between about 1 Torr and about 8 Torr, or a pressure of between about 1 Torr and about 6 Torr, or a pressure of between about 1 Torr and about 4 Torr, or a pressure of between about 1 Torr and about 2 Torr, or a pressure of between about 2 Torr and about 10 Torr, or a pressure of between about 2 Torr and about 8 Torr, or a pressure of between about 2 Torr and about 6 Torr, or a pressure of between about 2 Torr and about 4 Torr, or a pressure of between about 4 Torr and about 10 Torr, or a pressure of between about 4 Torr and about 8 Torr or a pressure of between about 4 Torr and about 6 Torr, or a pressure of between about 6 Torr and about 10 Torr or a pressure of between about 6 Torr and about 8 Torr, or a pressure of between about 8 Torr and about 10 Torr, or similar range.

At block 640, a high-temperature post-oxidation anneal (POA) process is performed. During the anneal process, at least a portion of the oxide layer 830 and/or the interfacial layer 820 is annealed to densify the formed oxide film(s). The radical oxidation process may be performed in a processing chamber, such as the same processing chambers as block 610, 620, and/or block 630, or a different processing chamber.

In some embodiments, the anneal process at block 640 is performed in an oxidant-free atmosphere. For example, in some embodiments, the anneal process is performed in a N₂ gas ambient, or another inert gas ambient.

In some embodiments, the anneal process at block 640 is performed at a high temperature of between about 100° C. and 500° C., or between about 800° C. and 1200° C., or between about 800° C. and 1100° C., or between about 800° C. and 1000° C., or between about 800° C. and 900° C., or between about 900° C. and 1200° C., or between about 900° C. and 1100° C., or between about 900° C. and 1000° C., or between about 1000° C. and 1200° C., or between about 1000° C. and 1100° C., or between about 1100° C. and 1200° C., or a similar range. The high temperature of the anneal process facilitates the relief of interfacial stress between the oxide layer 830, the interfacial layer 820, and/or the substrate 810, and further passivates oxygen vacancies and interfacial traps formed during method 600 with remaining trace amounts of oxidants. Additionally, impurities are outgassed from the formed oxide films to density such films.

In some embodiments the anneal process is performed for a period of between about 3 seconds and about 5 minutes, or more. For example, in some embodiments, the anneal process is performed for a period of between about 3 seconds and about 4 minutes, or for a period of between about 3 seconds and about 3 minutes, or for a period of between about 3 seconds and about 2 minutes, or for a period of between about 3 seconds and about 1 minute, or for a period of between about 1 minute and about 5 minutes, or for a period of between about 1 minute and about 4 minutes, or for a period of between about 1 minute and about 3 minutes, or for a period of between about 1 minute and about 2 minutes, or for a period of between about 2 minutes and about 5 minutes, or for a period of between about 2 minutes and about 4 minutes, or for a period of between about 2 minutes and about 3 minutes, or for a period of between about 3 minutes and about 5 minutes, or for a period of between about 3 minutes and about 4 minutes or for a period of between about 4 minutes and about 5 minutes, or similar duration.

In some embodiments, the anneal process at block 640 may be performed under a pressure of between about 500 mTorr and about 10 Torr. In some embodiments, the anneal process may be performed under a pressure of between about 500 m Torr and about 10 Torr. In some embodiments, the radical oxidation process may be performed under a pressure of between about 1 Torr and about 10 Torr, or a pressure of between about 1 Torr and about 8 Torr, or a pressure of between about 1 Torr and about 6 Torr, or a pressure of between about 1 Torr and about 4 Torr, or a pressure of between about 1 Torr and about 2 Torr, or a pressure of between about 2 Torr and about 10 Torr, or a pressure of between about 2 Torr and about 8 Torr, or a pressure of between about 2 Torr and about 6 Torr, or a pressure of between about 2 Torr and about 4 Torr, or a pressure of between about 4 Torr and about 10 Torr, or a pressure of between about 4 Torr and about 8 Torr or a pressure of between about 4 Torr and about 6 Torr, or a pressure of between about 6 Torr and about 10 Torr or a pressure of between about 6 Torr and about 8 Torr, or a pressure of between about 8 Torr and about 10 Torr, or similar range.

At block 650, a temperature ramp-down is performed. During the temperature ramp-down, the temperature within the processing chamber is decreased at a ramp rate of about 10° C./s, or more, until a desired temperature for a subsequent processing operation is reached. In some embodiments, the ramp-down rate is between about 10° C./s and 300° C./s. In some embodiments, the ramp-down rate is between about 10° C./s and about 200° C./s, or between 10° C./s and about 100° C./s, or between 100° C./s and about 300° C./s, or between 100° C./s and about 200° C./s, or between 200° C./s and about 300° C./s, or similar range. In some embodiments, the temperature ramp-down is performed for between about 3 seconds and about 20 seconds, such as between about 5 seconds and about 15 seconds, such as about 10 seconds, or similar duration.

In some embodiments, the temperature ramp-down at block 650 is performed in an oxidant-free atmosphere to inhibit further oxidation and maintain low interfacial roughness of the oxide layer 830 and the interfacial layer 820. For example, in some embodiments, the temperature ramp-down is performed in a N₂ gas ambient, or another inert gas ambient.

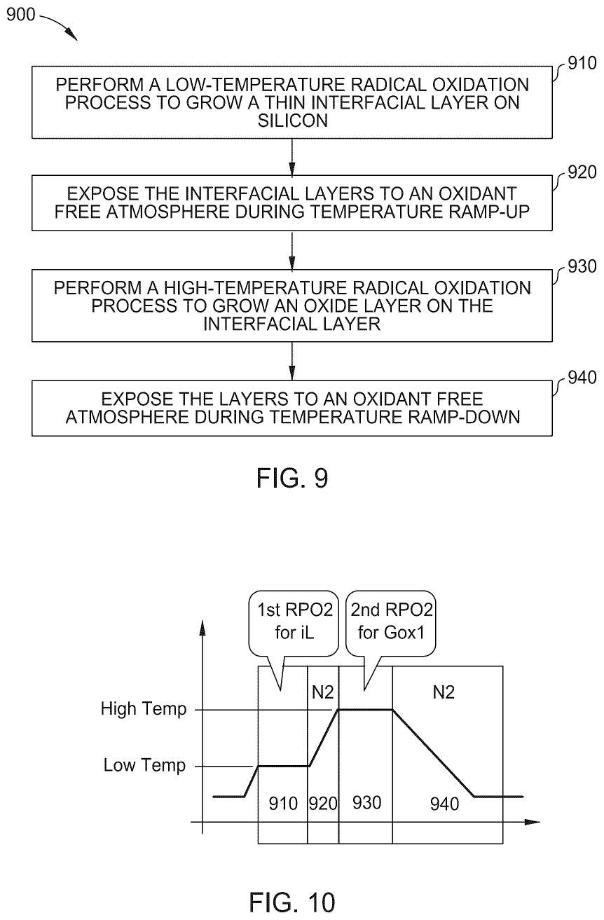

FIG. 9 depicts another process flow diagram of a method 900 for forming the example device structure 800, according to embodiments of the present disclosure. FIG. 10 depicts a graphical representation of the method 900, according to embodiments of the present disclosure. For clarity, Figures and 10 are herein described together for clarity. It should be understood that the operations depicted in FIGS. 9 and 10 may be performed simultaneously and/or in a different order than the order depicted in FIGS. 9 and 10.

The method 900 begins at block 910, in which the silicon-containing substrate 810 is exposed to a low-temperature radical oxidation process to grow, or form, the interfacial layer 820 on the substrate 810. During the radical oxidation process, at least a portion of the substrate 810 is oxidized to at least partially convert the silicon-containing material of the substrate to silicon oxide by a plasma radical oxidation process, such as remote plasma oxidation (RPO). The radical oxidation process may be performed in a processing chamber, such as one of the processing chambers 110, 112, 120, and 128 shown in FIG. 1, and/or the processing chamber 202 shown in FIG. 2.

In some embodiments, the radical oxidation process may use an oxidizing agent including oxygen (O₂), nitric oxide (NO), nitrous oxide (N₂O), or the like, to provide oxygen radicals (O*). These may be used alone or in a combination thereof. Further, the radical oxidation process may use a source gas for generating plasma including any combination of hydrogen (H₂) (of content ratio of 0% and about 80%), argon (Ar), helium (He), and xenon (Xe), among others. These may be used alone or in a combination thereof. For example, the source gas may include a combination of O₂ and Ar, O₂ and H₂, or O₂ and H₂ and Ar, among others.

In some embodiments, the radical oxidation process may allow an oxidation reaction at a temperature of between about 100° C. and 600° C. for a soak time of between about 3 seconds and about 3 minutes, to ensure high quality of the oxidized silicon. In some embodiments, the radical oxidation process is performed at a temperature of between about 100° C. and 500° C., or between about 100° C. and 400° C., or between about 100° C. and 300° C., or between about 100°° C. and 200° C., or between about 200° C. and 500° C., or between about 200° C. and 400° C., or between about 200° C. and 300° C., or between about 300° C. and 600° C., or between about 300° C. and 500° C., or between about 300° C. and 400° C., or between about 400° C. and 600° C., or between about 400° C. and 500° C., or between about 500° C. and 600° C., or a similar range.

In some embodiments, the radical oxidation process is performed for a period of between about 3 seconds and about 2 minutes, or for a period of between about 3 seconds and about 1 minute, or for a period of between about 30 seconds and about 3 minutes, or for a period of between about 30 seconds and about 2 minutes, or for a period of between about 30 seconds and about 1 minute, or for a period of between about 1 minute and about 3 minutes, or for a period of between about 1 minute and about 2 minutes, or for a period of between about 2 minutes and about 3 minutes, or similar duration.

In some embodiments, the radical oxidation process may be performed under a pressure of between about 500 mTorr and about 10 Torr. In some embodiments, the radical oxidation process may be performed under a pressure of between about 1 Torr and about 10 Torr, or a pressure of between about 1 Torr and about 8 Torr, or a pressure of between about 1 Torr and about 6 Torr, or a pressure of between about 1 Torr and about 4 Torr, or a pressure of between about 1 Torr and about 2 Torr, or a pressure of between about 2 Torr and about 10 Torr, or a pressure of between about 2 Torr and about 8 Torr, or a pressure of between about 2 Torr and about 6 Torr, or a pressure of between about 2 Torr and about 4 Torr, or a pressure of between about 4 Torr and about 10 Torr, or a pressure of between about 4 Torr and about 8 Torr or a pressure of between about 4 Torr and about 6 Torr, or a pressure of between about 6 Torr and about 10 Torr or a pressure of between about 6 Torr and about 8 Torr, or a pressure of between about 8 Torr and about 10 Torr, or similar range. The pressure may control an influx of the oxidizing agent against the substrate 810. The influx of the oxidizing agent may be controlled also by applying a bias during the radical oxidation process.

At block 920, a temperature ramp-up is performed. During the temperature ramp-up, the temperature within the processing chamber is increased at a ramp rate of about 10° C./s, or more, until a desired temperature for a second radical oxidation process is reached. In some embodiments, the ramp-up rate is between about 10° C./s and about 300° C./s. For example, in some embodiments, the ram-up rate is between about 10° C./s and about 200° C./s, or between 10° C./s and about 100° C./s, or between 100° C./s and about 300° C./s, or between 100° C./s and about 200° C./s, or between 200° C./s and about 300° C./s, or similar range. In some embodiments, the temperature ramp-up is performed for between about 3 seconds and about 20 seconds, such as between about 5 seconds and about 15 seconds, such as about 10 seconds, or similar duration.

In some embodiments, the temperature ramp-up at block 920 is performed in an oxidant-free atmosphere to inhibit further oxidation of the substrate 810 and maintain low interfacial roughness of the interfacial layer 820. Accordingly, in some embodiments where blocks 910-940 are performed in the same processing chamber, the oxygen radicals in the chamber may be purged at block 920, and N₂ gas or another inert gas may be flowed into the processing chamber. In some embodiments, however, the substrate 810 (now having the interfacial layer 820 formed thereon) may be transferred to another processing chamber for temperature ramp-up, wherein the substrate 810 may be exposed to N₂ gas or another inert gas.

In some embodiments, the temperature ramp-up at block 920 may be performed under a pressure of between about 500 mTorr and about 10 Torr. In some embodiments, the temperature ramp-up may be performed under a pressure of between about 1 Torr and about 10 Torr, or a pressure of between about 1 Torr and about 8 Torr, or a pressure of between about 1 Torr and about 6 Torr, or a pressure of between about 1 Torr and about 4 Torr, or a pressure of between about 1 Torr and about 2 Torr, or a pressure of between about 2 Torr and about 10 Torr, or a pressure of between about 2 Torr and about 8 Torr, or a pressure of between about 2 Torr and about 6 Torr, or a pressure of between about 2 Torr and about 4 Torr, or a pressure of between about 4 Torr and about 10 Torr, or a pressure of between about 4 Torr and about 8 Torr or a pressure of between about 4 Torr and about 6 Torr, or a pressure of between about 6 Torr and about 10 Torr or a pressure of between about 6 Torr and about 8 Torr, or a pressure of between about 8 Torr and about 10 Torr, or similar range.

At block 930, a second radical oxidation process is performed to grow, or form, an oxide layer 830 over the substrate interfacial layer 820. The radical oxidation process may be performed in a processing chamber, such as one of the processing chambers shown in FIG. 1, and/or the processing chamber 202 shown in FIG. 2.

In some embodiments, the second radical oxidation process at block 930 is a plasma radical oxidation process, such as remote plasma oxidation (RPO). In some embodiments, the plasma radical oxidation process may use an oxidizing agent including oxygen (O₂), nitric oxide (NO), nitrous oxide (N₂O), or the like, to provide oxygen radicals (O*). These may be used alone or in a combination thereof. Further, the plasma radical oxidation process may use a source gas for generating plasma including any combination of hydrogen (H₂) (of content ratio of 0% and about 80%), argon (Ar), helium (He), and xenon (Xe), among others. These may be used alone or in a combination thereof. For example, the source gas may include a combination of O₂ and Ar, O₂ and H₂, or O₂ and H₂ and Ar, among others.

In some embodiments, the second radical oxidation process may be performed at a high temperature. For example, the second radical oxidation process may be performed at a temperature of between about 700° C. and 1100° C. for a soak time of between about 3 seconds and about 3 minutes. In some embodiments, the radical second oxidation process is performed at a temperature of between about 700° C. and 1000° C., or between about 700° C. and 900° C., or between about 700° C. and 800° C., or between about 800° C. and 1100° C., or between about 800° C. and 1000° C., or between about 800° C. and 900° C., or between about 900° C. and 1100° C., or between about 900° C. and 1000° C., or between about 1000° C. and 1100° C., or a similar range. During this high-temperature radical oxidation process, the interfacial layer 820 may serve as a buffer layer to retard the oxidation rate, which results in bulk trap reduction by forming a more stoichiometric oxide layer 830, as well as a reduction in interfacial trap density (Dit) by passivating interfacial traps.

In some embodiments, the second radical oxidation process is performed for a period of between about 3 seconds and about 2 minutes, or for a period of between about 3 seconds and about 1 minute, or for a period of between about 30 seconds and about 3 minutes, or for a period of between about 30 seconds and about 2 minutes, or for a period of between about 30 seconds and about 1 minute, or for a period of between about 1 minute and about 3 minutes, or for a period of between about 1 minute and about 2 minutes, or for a period of between about 2 minutes and about 3 minutes, or similar duration.

In some embodiments, the second radical oxidation process may be performed under a pressure of between about 500 mTorr and about 10 Torr. The pressure may control an influx of the oxidizing agent. In some embodiments, the second radical oxidation process may be performed under a pressure of between about 1 Torr and about 10 Torr, or a pressure of between about 1 Torr and about 8 Torr, or a pressure of between about 1 Torr and about 6 Torr, or a pressure of between about 1 Torr and about 4 Torr, or a pressure of between about 1 Torr and about 2 Torr, or a pressure of between about 2 Torr and about 10 Torr, or a pressure of between about 2 Torr and about 8 Torr, or a pressure of between about 2 Torr and about 6 Torr, or a pressure of between about 2 Torr and about 4 Torr, or a pressure of between about 4 Torr and about 10 Torr, or a pressure of between about 4 Torr and about 8 Torr or a pressure of between about 4 Torr and about 6 Torr, or a pressure of between about 6 Torr and about 10 Torr or a pressure of between about 6 Torr and about 8 Torr, or a pressure of between about 8 Torr and about 10 Torr, or similar range. The influx of the oxidizing agent may be controlled also by applying a bias during the radical oxidation process.

At block 940, a temperature ramp-down is performed. During the temperature ramp-down, the temperature within the processing chamber is decreased at a ramp rate of about 10° C./s, or more, until a desired temperature for a subsequent processing operation is reached. In some embodiments, the ramp-down rate is between about 10° C./s and about 300° C./s. For example, in some embodiments, the ram-down rate is between about 10° C./s and about 200° C./s, or between 10° C./s and about 100° C./s, or between 100° C./s and about 300° C./s, or between 100° C./s and about 200° C./s, or between 200° C./s and about 300° C./s, or similar range. In some embodiments, the temperature ramp-down is performed for between about 3 seconds and about 20 seconds, such as between about 5 seconds and about 15 seconds, such as about 10 seconds, or similar duration.

In some embodiments, the temperature ramp-down at block 940 is performed in an oxidant-free atmosphere to inhibit further oxidation and maintain low interfacial roughness of the oxide layer 830 and the interfacial layer 820. For example, in some embodiments, the temperature ramp-down is performed in a N₂ gas ambient, or another inert gas ambient.

In summary, the present disclosure provides methods and devices for forming oxide layers for semiconductor device structures, such as gate oxides for buried wordline (bWL) structures used in dynamic random access memory (DRAM) devices, flash memory devices, programmable logic devices, CMOS devices, metal-oxide-semiconductor field-effect transistors (MOSFET), or the like. The methods and devices described herein address issues associated with more conventional fabrication methods, and provide for thin and high-quality oxide layers with controlled interfacial roughness. In some embodiments, the aforementioned oxide layers are formed using radical oxidation at relatively low-to-moderate temperatures, followed by nitrogen (N₂) annealing at relatively high temperatures to densify the oxide layer(s) while also relieving interfacial stress, or temperature ramp-downs in nitrogen or other inert gas ambients.

While the foregoing is directed to embodiments of the present disclosure, other and further embodiments of the disclosure may be devised without departing from the basic scope thereof, and the scope thereof is determined by the claims that follow.

1. A method for forming a semiconductor device, comprising:
performing a radical oxidation process to oxidize a silicon-containing material of a substrate and at least partially convert the silicon-containing material to an interfacial layer on the substrate, the radical oxidation process performed at a temperature between about 100° C. and about 600° C.;
performing a temperature ramp-up, the substrate exposed to an oxidant-free ambient during the temperature ramp-up;
performing an anneal process to densify the interfacial layer, the substrate exposed to the oxidant-free ambient during the anneal process, the anneal process performed at a temperature between about 800° C. and about 1200° C.;
performing a temperature ramp-down, the substrate exposed to the oxidant-free ambient during the temperature ramp-down; and
depositing an oxide layer over the annealed interfacial layer.

2. The method of claim 1, wherein the radical oxidation process comprises a plasma oxidation process.

3. The method of claim 2, wherein the plasma oxidation process comprises a remote plasma oxidation process.

4. The method of claim 1, wherein the interfacial layer has a thickness between about 1 Å and about 10 Å.

5. The method of claim 1, wherein the oxidant-free ambient during the temperature ramp-up or the temperature ramp-down comprises a N₂ gas ambient.

6. The method of claim 1, wherein the oxidant-free ambient during the anneal process comprises a N₂ gas ambient.

7. The method of claim 1, wherein the oxide layer is deposited via atomic layer deposition (ALD), epitaxial deposition, chemical vapor deposition (CVD), or physical vapor deposition (PVD).

8. A method for forming a semiconductor device, comprising:
performing a first radical oxidation process to oxidize a silicon-containing material of a substrate and at least partially convert the silicon-containing material to an interfacial layer, the first radical oxidation process performed at a temperature between about 100° C. and about 600° C.;
performing a second radical oxidation process to further oxidize the silicon-containing material of the substrate and at least partially convert the silicon-containing material to a base oxide layer for a gate oxide structure, the second radical oxidation process performed at a temperature between about 700° C. and about 800° C.;
performing a temperature ramp-up, the substrate exposed to an oxidant-free ambient during the temperature ramp-up;
performing an anneal process to densify the interfacial layer and the base oxide layer, the substrate exposed to the oxidant-free ambient during the anneal process, the anneal process performed at a temperature between about 800° C. and about 1200° C.; and
performing a temperature ramp-down, the substrate exposed to the oxidant-free ambient during the temperature ramp-down.

9. The method of claim 8, wherein the first radical oxidation process comprises a remote plasma oxidation process.

10. The method of claim 9, wherein the second radical oxidation process comprises a remote plasma oxidation process.

11. The method of claim 8, wherein the interfacial layer has a thickness between about 1 Å and about 10 Å.

12. The method of claim 8, wherein the oxidant-free ambient during the temperature ramp-up or the temperature ramp-down comprises a N₂ gas ambient.

13. The method of claim 8, wherein the oxidant-free ambient during the anneal process comprises a N₂ gas ambient.

14. A method for forming a semiconductor device, comprising:
performing a first radical oxidation process to oxidize a silicon-containing material of a substrate and at least partially convert the silicon-containing material to an interfacial layer, the first radical oxidation process performed at a temperature between about 100° C. and about 600° C.;
performing a temperature ramp-up, the substrate exposed to an oxidant-free ambient during the temperature ramp-up;
performing a second radical oxidation process to further oxidize the silicon-containing material of the substrate and at least partially convert the silicon-containing material to a base oxide layer for a gate oxide structure, the second radical oxidation process performed at a temperature between about 700° C. and about 1100° C.; and
performing a temperature ramp-down, the substrate exposed to the oxidant-free ambient during the temperature ramp-down.

15. The method of claim 14, wherein the first radical oxidation process comprises a remote plasma oxidation process.

16. The method of claim 15, wherein the second radical oxidation process comprises a remote plasma oxidation process.

17. The method of claim 14, wherein the interfacial layer has a thickness between about 1 Å and about 10 Å.

18. The method of claim 14, wherein the oxidant-free ambient during the temperature ramp-up comprises a N₂ gas ambient.

19. The method of claim 18, wherein the oxidant-free ambient during the temperature ramp-down comprises a N₂ gas ambient.

20. The method of claim 18, wherein a temperature ramp rate during the temperature ramp-up is between about 10° C./s and about 300° C./s.
